(19) United States
(12) Patent Application Publication
(10) Pub. No.: US 2025/0385113 A1
(43) Pub. Date: Dec. 18, 2025

(54) WAFER CONTAINER HOUSING AND A WAFER CONTAINER TRANSFERRING METHOD

(71) Applicant: STATS ChipPAC Pte. Ltd., Singapore (SG)

(72) Inventors: WengOnn CHANG, Singapore (SG); ChunTiong TANG, Singapore (SG)

(21) Appl. No.: 19/241,338

(22) Filed: Jun. 17, 2025

(30) Foreign Application Priority Data
Jun. 18, 2024 (CN) 202410787477.2

(51) Int. Cl. H01L 21/673; B65G 47/90; H01L 21/677

(52) U.S. Cl. CPC H01L 21/67386; B65G 47/90; H01L 21/67373; H01L 21/6773

(57) ABSTRACT

A wafer container housing comprises a main frame defining a container storage space to accommodate a first wafer container for holding a first set of wafers, and the main frame having a size substantially the same as that of a second wafer container for holding a second set of wafers, wherein the first set of wafers have a diameter smaller than that of the second set of wafers; and a knob extending upward from a top portion of the main frame and engageable with an automated conveyer to allow for transfer of the wafer container housing by the automated conveyer.

### TECHNICAL FIELD

The present application generally relates to semiconductor technology, and more particularly, to a wafer container housing and a wafer container transferring method.

### BACKGROUND OF THE INVENTION

Wafer containers are widely used to contain silicon wafers or other types of wafers that are used in the manufacturing of integrated circuits. The wafer containers may provide a microenvironment to isolate and control the volume surrounding wafers, to reduce or avoid damages or contaminants to the wafers. Depending on the size of the wafers, various wafer containers are provided with different sizes, shapes and structures.

An existing design of front opening shipping boxes (FOSBs) for 300 mm wafers, which are a type of wafer container, has a knob on its top to cater for an automated material handling system (AMHS) to transfer the FOSB between tools at a semiconductor foundry. However, there is no such knob design for wafer containers that are used to contain 150 mm and 200 mm wafers, which may also be handled or processed in the same foundry. As such, different container transferring or conveying tools may be needed to handle these different wafers. Therefore, a need exists to transfer different sized wafers in a more efficient way.

### SUMMARY OF THE INVENTION

An objective of the present application is to provide a wafer container housing to allow for transferring different sized wafer containers using the same conveyer.

According to an aspect of the present application, there is provided a wafer container housing, which comprises: a main frame defining a container storage space to accommodate a first wafer container for holding a first set of wafers, and the main frame having a size substantially the same as that of a second wafer container for holding a second set of wafers, wherein the first set of wafers have a diameter smaller than that of the second set of wafers; and a knob extending upward from a top portion of the main frame and engageable with an automated conveyer to allow for transfer of the wafer container housing by the automated conveyer.

In another aspect of the present application, a wafer container transferring method is provided, which comprises: providing a wafer container housing; accommodating a first wafer container for holding a first set of wafers within the wafer container housing, wherein the wafer container housing has a size substantially the same as that of a second wafer container for holding a second set of wafers, and the first set of wafers have a diameter smaller than that of the second set of wafers; engaging the wafer container housing with an automated conveyer; and transferring the wafer container housing and the first wafer container by the automated conveyer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a front perspective view of a substrate container assembly 10 configured as a wafer container.

FIG. 2 illustrates a wafer container housing according to an embodiment of the present application.

FIG. 3 illustrates the wafer container housing shown in FIG. 2 in which a wafer container is accommodated.

FIG. 4 illustrates a cross sectional view of the wafer container housing and the wafer container shown in FIG. 3.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, different sized wafer containers such as those used to contain 150 mm, 200 mm, or 300 mm wafers are widely used in a semiconductor foundry or a backend packaging site, all of which may be handled or transferred by automated conveyers or other similar conveying tools. However, the difference in size and structure of the wafer containers increases difficulty in transferring them. For example, two or more types of conveying tools may be needed to transfer two or more sized wafer containers, respectively.

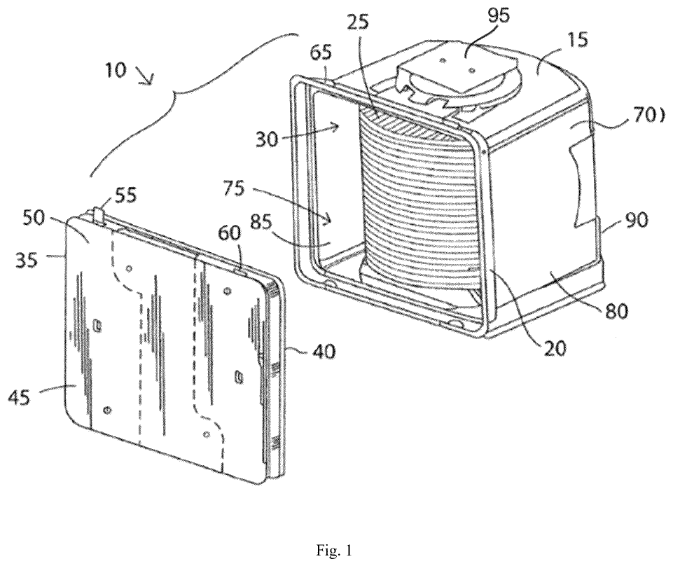

FIG. 1 is a front perspective view of a substrate container assembly 10 configured as a wafer container. The substrate container assembly 10 may be used to contain a set of 300 mm wafers, for example. The assembly 10 includes a container 15 adapted to support one or more semiconductor wafers 20 or other substrates in stack within a microenvironment or wafer storage area 30. The container 15 has a door 35 for sealingly closing the container 15 and for opening the container 15 to allow access to the wafer storage area 30. The door 35 has an interior side 40, facing the wafer storage area 30, and an exterior side 45, facing away from the wafer storage area 30. The door 35 includes a door housing 50 with a latching mechanism including tabs 55 extending from apertures 60 into corresponding recesses 65 in the container 15 to secure the door 35 closed. The container 15 defines an exterior 70 and an interior 75. The wafer storage area 30 is disposed within the container interior 75. The container 15 includes side walls 80, 85, with the door 35 and a back wall 90 extending between the side walls 80, 85. The back wall 90 is opposite to the door 35.

Moreover, a knob 95 may extend upward from the exterior 70 of the container 15, which may be attached to a conveying tool such as an automated mobile robot or an automated material handling system so as to facilitate transfer of the substrate container assembly 10 by such conveying tool. However, containers for 150 mm or 200 mm wafers do not have the knob due to the difference in size and shape from the 300 mm containers, and thus may not be handled by the same conveying tool.

In order to address the above issue, a wafer container housing is provided according to some embodiments of the present application. The wafer container housing may be used to accommodate a smaller wafer container (e.g., for containing 150 mm or 200 mm wafers) therein, thereby enlarging the size of the smaller wafer container and changing the shape and structure of the smaller wafer container. In this way, the smaller container may have a size, shape and structure that comply with a conveying tool that is used to handle or transfer bigger wafer containers (e.g., for containing 300 mm wafers), and can thus be handled by such bigger conveying tool, eliminating or at least reducing the need to use conveying tools designed specifically for the smaller wafer containers.

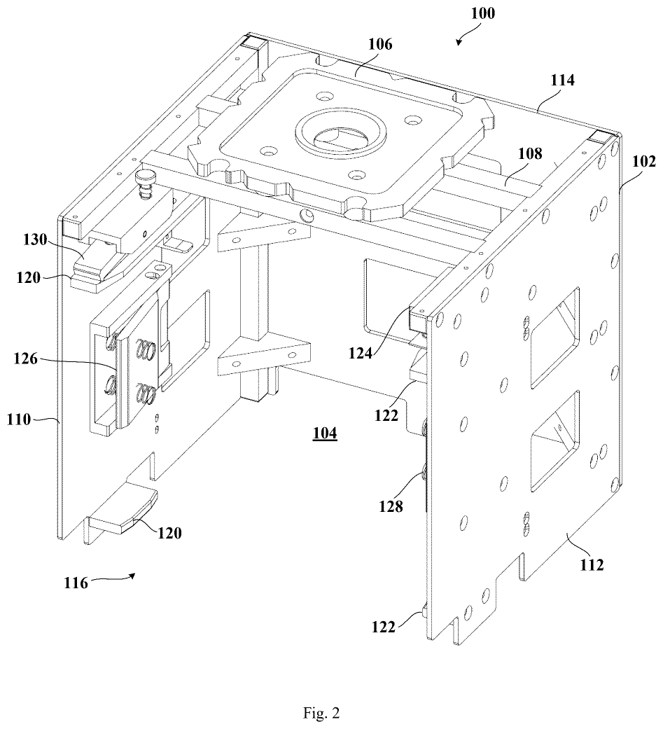

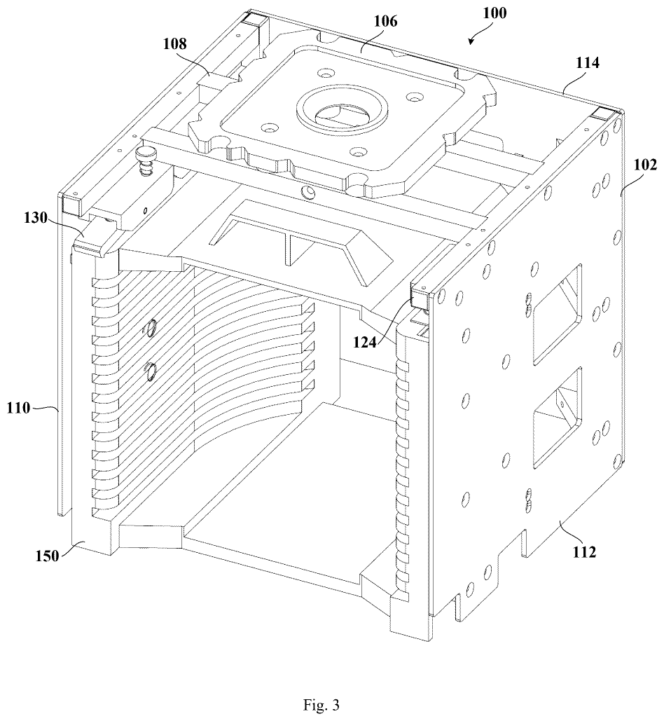

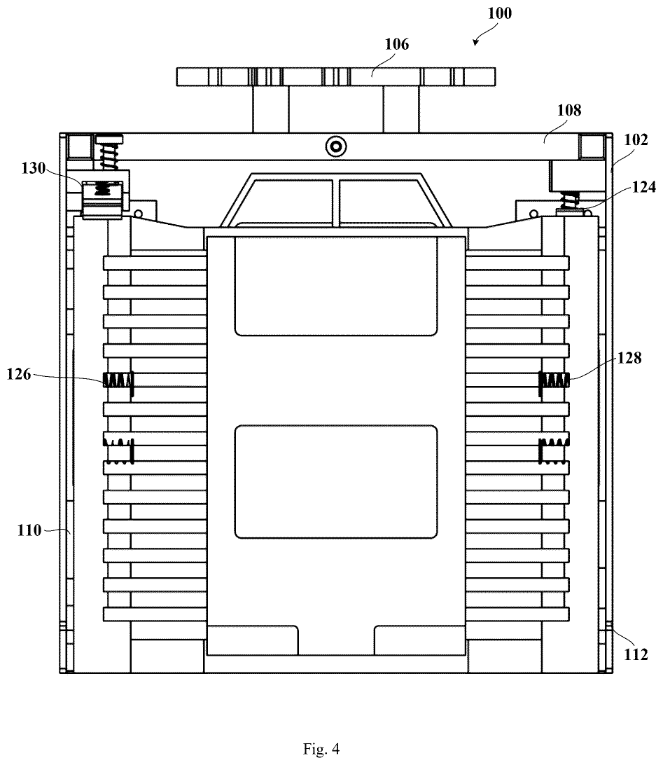

FIGS. 2 to 4 show a wafer container housing 100 according to an embodiment of the present application. In particular, FIG. 2 shows the wafer container housing 100 with no wafer container, while FIGS. 3 and 4 show a perspective view and a cross sectional view of the wafer container housing 100 with a wafer container 150 accommodated therein, respectively.

As shown in FIGS. 2 to 4, the wafer container housing 100 has a main frame 102 defining a container storage space 104 to accommodate the wafer container 150. The wafer container 150 may be used to hold a set of wafers (not shown), which may be, for example, 150 mm wafers or 200 mm wafers. When the wafer container 150 is accommodated within the wafer container housing 100, the main frame 102 can increase significantly a total size of the wafer containing device, i.e., from a size of the wafer container 150 to a size of the wafer container housing 100. In some embodiments, the main frame 102 may have a size substantially the same as that of another type of wafer container (e.g., a front opening shipping box shown in FIG. 1) for holding another set of wafers which have a diameter greater than that of the set of wafers accommodatable within the wafer container 150. In this way, the wafer container 150 which may not be compatible with a conveying tool designed for handling or transferring a bigger wafer container can therefore be handled and transferred by such conveying tool.

Furthermore, the wafer container housing 100 further includes a knob 106, which extends upward from a top portion 108 of the main frame 102 to an exterior of the main frame 102. The knob 106 may be mounted to the main frame 102 in any suitable means such as a fastener. The knob 106 is such designed that it is engageable with an automated conveyer to allow for transfer of the wafer container housing 100 by the automated conveyer. In some embodiments, the knob 106 may have a size or shape similar as the knob 95 shown in FIG. 1 which is used in a 300 mm wafer container assembly. As such, the wafer container housing 100 can be picked up and handled by the conveying tool designed for handling or transferring 300 mm wafer container assemblies. It can be appreciated that the shape or structure of the knob 106 may not be identical to the existing knobs for 300 mm wafer container assemblies or other bigger wafer containers, as long as the engagement between the knob 106 and the conveying tool can be implemented. In some other embodiments, the knob 106 may be releasably mounted to the main frame 102, such that the knob of the wafer container housing 100 may be replaced with another knob with a different design to comply with a different conveying tool depending on what specific type of wafer container the wafer container housing 100 is “mimicking”.

Still referring to FIGS. 2 to 4, the main frame 102 is shaped as a cuboid, with at least the top portion 108, two side walls 110 and 112, and a rear wall 114 assembled together. The side walls 110 and 112 are parallel plates, which are generally opposite to each other with respect to the cuboid main frame 102. Furthermore, the main frame 102 defines at its lateral side a front opening 116 which is opposite to the rear wall 114. Through the front opening 116, the wafer container 150 can be inserted into the container storage space 104 and accommodated therein. For example, a pair of rails 120 and 122 may be formed on the two side walls 110 and 112, respectively, both of which may extend between the front opening 116 and the rear wall 114. The pairs of rails 120 and 122 can receive respective tabs (not shown) at an exterior of the wafer container 150. In this way, the wafer container 150 can slide from the exterior of the main frame 102 into the main frame 102 through the front opening 116, to be accommodated within the container storage space 104. When it is desired to remove the wafer container 150, the wafer container 150 can slide out of the main frame along the rails 120 and 122, as long as certain locking components inside the main frame 102 are released. It can be appreciated that the rail 120 or 122 on one of the two side walls 110 and 112 may have two or more slots or ribs which may be aligned with the respective tabs of the wafer container 150 vertically. As such, the vertical movement of the wafer container 150 within the wafer container housing 100 may be substantially reduced or avoided.

As aforementioned, in some embodiments, one or more container locking components may be disposed on the main frame 102, to secure the wafer container 150 therewith when it is accommodated within the container storage space 104. For example, a locking component 124 may be disposed in the rail 122 on the side wall 112. The locking component 124 may apply a biasing force perpendicular to the rail 122 where it resides to prohibit a vertical movement of the wafer container 150 when the wafer container 150 is accommodated within the container storage space 104. For example, the locking component 124 may include a compression plate and a bias spring that connects the compression plate with the side wall 112. The locking component 124 in the rail 122 ensures further securement of the wafer container 150 with the main frame 102. It can be appreciated that the locking component 124 may take other forms as desired, and is not limited to the example described above. Optionally, another locking component (not shown) may be disposed in the rail 120 on the other side wall 110, and can be symmetrical to the locking component 124 in position.

The wafer container housing 100 may include other locking components that are used to secure the wafer container 150 with the main frame 102 in other orientations. For example, two locking components 126 and 128 may be disposed on the side walls 110 and 112, respectively, with an orientation different from the locking components within the pair of rails 120 and 122. In particular, when the wafer container 150 is accommodated within the container storage space 104, each of the pair of locking components 126 and 128 may apply a biasing force towards the container storage space 104 to prohibit a translational movement of the wafer container 150 between the side walls 110 and 112. Each of the locking components 126 and 128 may similarly include a compression plate and a bias spring that contacts the compression plate with the side wall 110 or 112, but may have a bigger size than the locking component within the rails. Furthermore, another locking component 130 may be disposed on one of the side walls 110 and 112 and close to the front opening 116. When the wafer container 150 is accommodated within the container storage space 104, the locking component 130 may apply a bias force from the front opening 116 to the rear wall 114 to prohibit a translational movement of the wafer container 150 between the front opening 116 and the rear wall 114 and against the rear wall 114. For example, the locking component 130 may be a retention pin pivotally mounted to the side wall 110 and biased by a bias spring. When the wafer container 150 slides into the main frame 102 in full, the retention pin may move downward to prevent the wafer container 150 from sliding out of the main frame 102.

With the various locking components as aforementioned, the wafer container 150 can be secured firmly within the wafer container housing 100, and thus can be moved along with the wafer container housing 100, for example, by a conveying tool that picks up the wafer container housing 100 at the knob 106. It can be appreciated that the locking components inside the wafer container housing 100 may be releasably mounted onto the interior of the wafer container housing 100, and thus may be moved in position and/or be replaced with other locking components, so as to be used to secure wafer containers of different sizes, shapes and/or structures within the housing 100. In some embodiments, one or more of the locking components may be self-locking, which may apply the bias force to the wafer container once it is in place. In some other embodiments, an additional handle, pin or button may be mechanically coupled to a locking component, which may help to switch the locking component between a locked position and a released position, for example, by a user operation or an automated machine operation.

In some embodiments, other than the front opening 116, the main frame 102 may have one or more windows for observation or other similar purpose. The window may be aligned with a container identification or scan code at the exterior of the wafer container 150, such that the container identification or scan code can be observed, scanned, detected or otherwise accessible from the exterior of the wafer container housing. In this way, an operator or an automated conveying tool can know which specific wafer container is accommodated within the wafer container housing 100 without pulling it out.

In the embodiment shown in FIGS. 2 to 4, the main frame 102 has two sides that are generally open, i.e., the side where the front opening 116 is, and the bottom side. In some other alternative embodiments, the rear side of the main frame 102, i.e., the side opposite to the front opening 116, may be open. In that case, additional retention means or locking components may be mounted to the side walls 110 and 112 to prevent the translation movement of the wafer container 150 between the front side and the rear side. Preferably, the main frame 102 and the locking components therein may be so configured that the wafer container 150 may slide into the container housing 100 through the front opening 116, to be accommodated within the container storage space 104, and may then slide out of the container housing 100 through rear opening that is opposite to the front opening 116. Also, in some embodiments, a bottom plate (not shown) may be assembled with the side walls 110 and 112 at the bottom side of the main frame 102 as a part of the main frame 102. It can be appreciated that the main frame 102 may take any other forms as long as it can provide sufficient robustness for accommodating and protecting wafer containers when they are handled or transferred by conveying tools.

The wafer container housing shown in FIGS. 2 to 4 may be used to implement a wafer container transferring method. The method comprises providing a wafer container housing; accommodating a first wafer container for holding a first set of wafers within the wafer container housing, wherein the wafer container housing has a size substantially the same as that of a second wafer container for holding a second set of wafers, and the first set of wafers have a diameter smaller than that of the second set of wafers; engaging the wafer container housing with an automated conveyer; and transferring the wafer container housing and the first wafer container by the automated conveyer.

In some embodiments, the wafer container housing further comprises one or more container locking components, and the method further comprises: securing the first wafer container within the wafer container housing by the one or more container locking components.

The discussion herein includes numerous illustrative figures that show various portions of a wafer container housing and a wafer container transferring method. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A wafer container housing, comprising:
a main frame defining a container storage space to accommodate a first wafer container for holding a first set of wafers, and the main frame having a size substantially the same as that of a second wafer container for holding a second set of wafers, wherein the first set of wafers have a diameter smaller than that of the second set of wafers; and
a knob extending upward from a top portion of the main frame and engageable with an automated conveyer to allow for transfer of the wafer container housing by the automated conveyer.

2. The wafer container housing of claim 1, wherein the main frame is shaped as a cuboid, and defines at its lateral side a front opening through which the first wafer container can be inserted into the container storage space and accommodated therein.

3. The wafer container housing of claim 2, wherein the wafer container housing further comprises:
one or more container locking components for securing the first wafer container with the main frame when it is accommodated within the container storage space.

4. The wafer container housing of claim 3, wherein the main frame comprises a first side wall and a second side wall adjacent to the front opening, and a rear wall opposite to the front opening, and wherein the one or more container locking components are disposed on the first side wall and the second side wall.

5. The wafer container housing of claim 4, wherein the one or more container locking components comprises:
a first container locking component disposed on the first side wall, and a second container locking component disposed on the second side wall, wherein each of the first and second container locking components is configured to apply a biasing force towards the container storage space to prohibit a translational movement of the first wafer container between the first side wall and the second side wall when the first wafer container is accommodated within the container storage space.

6. The wafer container housing of claim 4, further comprising a first rail formed on the first side wall and a second rail formed on the second side wall; wherein the first rail and the second rail both extend between the front opening and the rear wall, and are configured to receive respective tabs at an exterior of the first wafer container, to allow the first wafer container to slide into or out of the main frame through the front opening.

7. The wafer container housing of claim 6, wherein the one or more container locking components comprises:
a third container locking component disposed in the first rail and a fourth container locking component disposed in the second rail; wherein each of the third and fourth container locking components is configured to apply a bias force perpendicular to the corresponding rail to prohibit a vertical movement of the first wafer container when the first wafer container is accommodated within the container storage space.

8. The wafer container housing of claim 4, wherein the one or more container locking components comprises:
a fifth container locking component disposed on one of the first and second side walls and close to the front opening, and configured to apply a bias force towards the rear wall to prohibit a translational movement of the first wafer container between the front opening and the rear wall when the first wafer container is accommodated within the container storage space.

9. The wafer container housing of claim 1, wherein the main frame further comprises one or more windows through which a portion of the wafer container can be observed.

10. A wafer container transferring method, comprising:
providing a wafer container housing;
accommodating a first wafer container for holding a first set of wafers within the wafer container housing, wherein the wafer container housing has a size substantially the same as that of a second wafer container for holding a second set of wafers, and the first set of wafers have a diameter smaller than that of the second set of wafers;
engaging the wafer container housing with an automated conveyer; and
transferring the wafer container housing and the first wafer container by the automated conveyer.

11. The wafer container transferring method of claim 10, wherein the wafer container housing further comprises one or more container locking components, and the method further comprises:
securing the first wafer container within the wafer container housing by the one or more container locking components.
